(19) United States
(12) Patent Application Publication
(10) Pub. No.: US 2023/0128495 A1
(43) Pub. Date: Apr. 27, 2023

(54) 3D TRANSISTOR STACKING USING NON-EPITAXIAL COMPOUND SEMICONDUCTOR

(71) Applicant: Tokyo Electron Limited, Tokyo (JP)

(72) Inventors: H. Jim FULFORD, Marianna, FL (US); Mark I. GARDNER, Cedar Creek, TX (US); Partha MUKHOPADHYAY, Oviedo, FL (US)

(73) Assignee: Tokyo Electron Limited, Tokyo (JP)

(21) Appl. No.: 17/742,893

(22) Filed: May 12, 2022

Related U.S. Application Data
(60) Provisional application No. 63/270,996, filed on Oct. 22, 2021.

(51) Int. Cl. H01L 29/423; H01L 27/06; H01L 21/8258; H01L 29/786; H01L 29/06; H01L 29/417; H01L 29/22; H01L 29/24

(52) U.S. Cl. CPC H01L 29/42392; H01L 27/0688; H01L 21/8258; H01L 29/78696; H01L 29/0665; H01L 29/41775; H01L 29/22; H01L 29/24

(57) ABSTRACT

A semiconductor device includes a stack of transistors stacked over a base in a direction substantially perpendicular to a working surface of the base. Each transistor includes a respective channel structure, respective source/drain (S/D) regions positioned on ends of the respective channel structure, and a respective gate structure disposed all around the respective channel structure. Each channel structure includes a respective non-epitaxial compound semiconductor.

### INCORPORATION BY REFERENCE

This present disclosure claims the benefit of U.S. Provisional Application No. 63/270,996, filed on Oct. 22, 2021, which is incorporated herein by reference in its entirety. Aspects of the present disclosure are related to Applicant's co-pending U.S. patent application Ser. No. 17/714,678, filed on Apr. 6, 2022, which is incorporated herein by reference in its entirety.

### FIELD OF THE INVENTION

This disclosure relates to microelectronic devices including semiconductor devices, transistors, and integrated circuits, and methods of microfabrication.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane, and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other.

### SUMMARY

The present disclosure relates to a semiconductor device and a method of forming the same.

Aspect (1) includes a semiconductor device. The semiconductor device includes a stack of transistors stacked over a base in a direction substantially perpendicular to a working surface of the base. Each transistor includes a respective channel structure, respective source/drain (S/D) regions positioned on ends of the respective channel structure, and a respective gate structure disposed all around the respective channel structure. Each channel structure includes a respective non-epitaxial compound semiconductor.

Aspect (2) includes the semiconductor device of Aspect (1), wherein at least two channel structures includes a same chemical composition.

Aspect (3) includes the semiconductor device of Aspect (1), wherein at least two channel structures include different chemical compositions.

Aspect (4) includes the semiconductor device of Aspect (1), wherein at least one non-epitaxial compound semiconductor is an oxide semiconductor or a metal chalcogenide.

Aspect (5) includes the semiconductor device of Aspect (4), wherein the oxide semiconductor is In₂O₃, SnO₂, InGaZnO, ZnO, SnO or CdO.

Aspect (6) includes the semiconductor device of Aspect (4), wherein the metal chalcogenide is WS₂, WSe₂, WTe₂, MoS₂, MoSe₂, MoTe₂, HfS₂, ZrS₂, TiS₂, GaSe, InSe or TiS₃.

Aspect (7) includes the semiconductor device of Aspect (1), wherein one or more S/D regions include a metal.

Aspect (8) includes the semiconductor device of Aspect (1), wherein at least one transistor includes a plurality of channel structures. Respective S/D regions of the at least one transistor are in direct contact with the plurality of channel structures. A respective gate structure of the at least one transistor is disposed all around the plurality of channel structures.

Aspect (9) includes the semiconductor device of Aspect (1), further including inner spacers disposed between gate structures and respective S/D regions.

Aspect (10) includes the semiconductor device of Aspect (1), wherein at least one gate structure includes a gate metal and a gate dielectric.

Aspect (11) includes the semiconductor device of Aspect (1), wherein the base is positioned immediately below the stack of transistors. The base includes a dielectric material or a semiconductor material.

Aspect (12) includes the semiconductor device of Aspect (1), further including isolation structures between transistors.

Aspect (13) includes a method of microfabrication. The method includes forming an initial stack of layers surrounded by a sidewall structure. The initial stack of layers includes channel structures and sacrificial gate layers stacked alternatingly. The channel structures include non-epitaxial compound semiconductor material. First portions of the sidewall structure are removed to uncover first sides of the initial stack. Source/drain (S/D) regions are formed on uncovered side surfaces of the channel structures from the first sides of the initial stack. Second portions of the sidewall structure are removed to uncover second sides of the initial stack. The sacrificial gate layers are replaced with gate structures from the second sides of the initial stack.

Aspect (14) includes the method of Aspect (13), wherein the forming the S/D regions includes selectively depositing a metal material on uncovered side surfaces of at least one channel structure from the first sides of the initial stack.

Aspect (15) includes the method of Aspect (13), wherein the forming the S/D regions includes depositing a first metal material from the first sides of the initial stack. The first metal material is etched back to form first S/D regions on opposing ends of at least one first channel structure. An isolation structure is formed over the first S/D regions. A second metal material is deposited to form second S/D regions on opposing ends of at least one second channel structure.

Aspect (16) includes the method of Aspect (13), wherein the sacrificial gate layers include one or more first sacrificial gate layers in direct contact with one or more first channel structures and one or more second sacrificial gate layers in direct contact with one or more second channel structures positioned above the one or more first channel structures. The replacing the sacrificial gate layers with the gate structures includes forming a protective structure to cover respective side surfaces of the one or more second sacrificial gate layers from the second sides of the initial stack. The one or more first sacrificial gate layers are replaced with one or more first gate structures.

Aspect (17) includes the method of Aspect (16), further including removing the protective structure. The one or more second sacrificial gate layers are replaced with one or more second gate structures.

Aspect (18) includes the method of Aspect (16), wherein the removing the second portions of the sidewall structure includes removing upper parts of the second portions of the sidewall structure before the forming the protective structure. Lower parts of the second portions of the sidewall structure are removed after the forming the protective structure.

Aspect (19) includes the method of Aspect (13), further including forming indentations by removing end portions of the sacrificial gate layers from the first sides of the initial stack. Inner spacers are formed in the indentations.

Aspect (20) includes the method of Aspect (13), wherein the forming the initial stack of layers includes forming a stack of layers. The stack of layers includes alternating layers of dielectric material and non-epitaxial compound semiconductor material. The stack of layers is directionally etched to form the initial stack of layers. One or more dielectric materials are deposited around the initial stack of layers to form the sidewall structure.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIG. 1A shows a top view of a semiconductor device, in accordance with one embodiment of the present disclosure.

FIG. 1B shows a vertical cross-sectional view taken along the line cut AA′ in FIG. 1A, in accordance with one embodiment of the present disclosure.

FIG. 1C shows a vertical cross-sectional view taken along the line cut BB′ in FIG. 1A, in accordance with one embodiment of the present disclosure.

FIG. 2A shows a top view of a semiconductor device, in accordance with another embodiment of the present disclosure.

FIG. 2B shows a vertical cross-sectional view taken along the line cut CC′ in FIG. 2A, in accordance with one embodiment of the present disclosure.

FIG. 2C shows a vertical cross-sectional view taken along the line cut DD′ in FIG. 2A, in accordance with one embodiment of the present disclosure.

FIG. 3 shows a flow chart of a process for manufacturing a semiconductor device, in accordance with some embodiments of the present disclosure.

FIGS. 4A, 4B, 4C, 4D, 4E, 4F, 4G and 4H show top views of a semiconductor device at various intermediate steps of manufacturing, in accordance with some embodiments of the present disclosure.

FIGS. 4A′, 4B′, 4C′, 4D′, 4E′, 4F′, 4G′ and 4H′ respectively show vertical cross-sectional views of the semiconductor device in FIGS. 4A, 4B, 4C, 4D, 4E, 4F, 4G and 4H, in accordance with some embodiments of the present disclosure.

FIG. 4F″ show another vertical cross-sectional view of the semiconductor device in FIG. 4F, in accordance with one embodiment of the present disclosure.

FIGS. 5A, 5B and 5C show top views of a semiconductor device at various intermediate steps of manufacturing, in accordance with some embodiments of the present disclosure.

FIGS. 5A′, 5B′ and 5C′ respectively show vertical cross-sectional views of the semiconductor device in FIGS. 5A, 5B and 5C, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

3D integration, i.e. the vertical stacking of multiple devices, aims to overcome scaling limitations experienced in planar devices by increasing transistor density in volume rather than area. Although device stacking has been successfully demonstrated and implemented by the flash memory industry with the adoption of 3D NAND, application to random logic designs is substantially more difficult. 3D integration for logic chips (CPU (central processing unit), GPU (graphics processing unit), FPGA (field programmable gate array, SoC (System on a chip)) is being pursued. 3D integration often entails stacking semiconductor materials in the vertical direction, for instance in order to stack semiconductor channels, semiconductor sources, semiconductor drains, etc.

“Epitaxy” (also known as epitaxial growth or epitaxial deposition) herein generally refers to a type of crystal growth or material deposition in which a crystalline layer is formed over a seed layer that is crystalline. Crystalline characteristics (e.g. crystal orientation) of the crystalline layer are related to or dictated by crystalline characteristics of the seed layer. Epitaxy is widely used for depositing traditional semiconductor materials, such as elemental semiconductors, e.g. Si and Ge, and epitaxial compound semiconductors, e.g. GaN, GaAs, InP and InGaN. Nevertheless, stacking semiconductor materials in the vertical direction via a series of epitaxial deposition inevitably requires a series of seed layers, which can place a heavy burden on semiconductor design and manufacture.

Techniques herein disclose methods of fabricating microelectronic devices using dielectric conductive materials (e.g. oxide semiconductor materials or other non-epitaxial compound semiconductors) instead of traditional semiconductor materials. Because semiconductor materials (e.g. silicon, germanium, et cetera) or a semiconductor substrate (e.g. a silicon wafer) is not needed herein as a seed layer, relatively high or great stacking of layers can be achieved using 3D nanosheet architecture. In other words, any base layer or base material can replace a conventional semiconductor substrate. Another advantage herein is that no epitaxial growth of semiconductor channels or source/drain is needed, which can enable an efficient flow with low Dt. Also enabled are very low off-state leakage currents. Techniques herein enable additional stacking of 3D devices on top of existing 3D devices for a higher circuit density. Both 3D stacks of horizontal conductive channel nanosheets in both CFET and side-by-side transistors are enabled.

Techniques herein include forming transistor and other microelectronic devices using a semiconductor-like dielectric. This is also referred to as a conductor channel in the description or a non-epitaxial compound semiconductor. A non-epitaxial compound semiconductor herein refers to a compound semiconductor that does not need to be formed by epitaxy and yet may be crystalline. A non-epitaxial compound semiconductor herein can include a compound in which the individual elements are not semiconductor elements. For example, a non-epitaxial compound semiconductor herein does not include Si or Ge. Certain types of elements when combined with oxygen can form a new material that shows semiconductor properties (that is, these materials can turn off with low-off state leakage current or can become highly conductive). Such materials do not require epitaxy to be crystalline and are often referred to as oxide semiconductors or semiconducting oxides. Examples of N-type oxide semiconductors (e.g. used as conductive channels) include In₂O₃, InGaZnO, CdO and ZnO. Examples of P-type oxide semiconductors (e.g. used as conductive channels) include SnO and SnO₂.

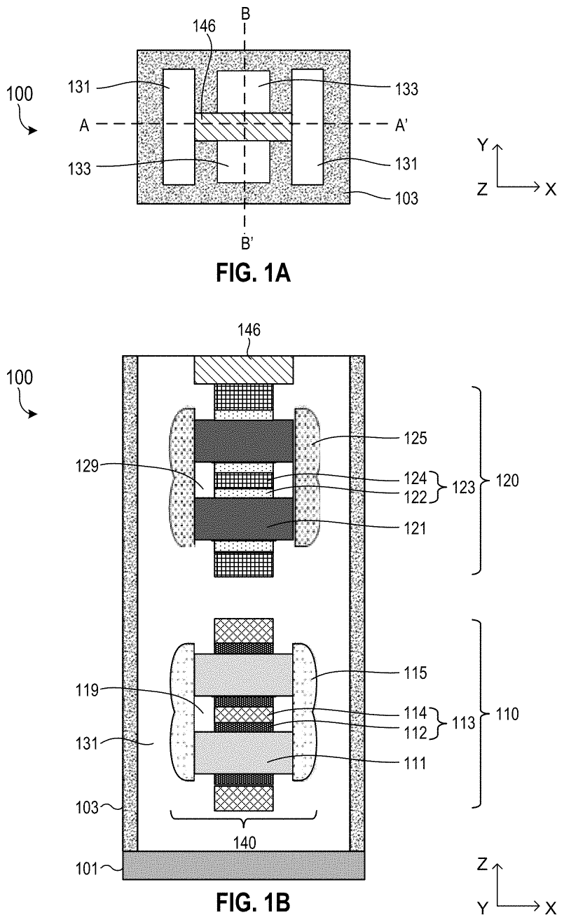

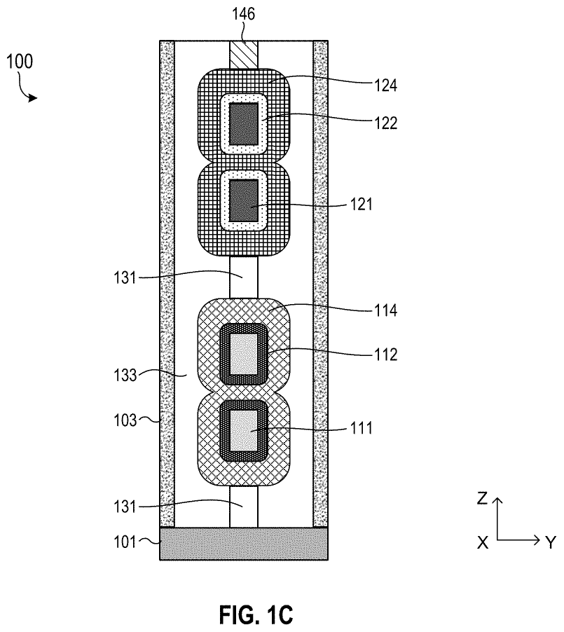

FIG. 1A shows a top view of a semiconductor device 100, in accordance with one embodiment of the present disclosure. FIGS. 1B and 1C respectively show vertical cross-sectional views taken along the line cuts AA′ and BB′ in FIG. 1A, in accordance with some embodiments of the present disclosure.

The semiconductor device 100 includes at least one stack 140 of transistors (e.g. 110 and 120) stacked over a base 101 in a direction (e.g. the Z direction) substantially perpendicular to a working surface of the base 101. Each transistor can include at least one respective channel structure (e.g. 111 and 121), respective source/drain (S/D) regions (e.g. 115 and 125) positioned on respective ends of the at least one respective channel structure, and at least one respective gate structure (e.g. 113 and 123) disposed all around the at least one respective channel structure.

In a non-limiting example, the semiconductor device 100 includes a first transistor 110 and a second transistor 120. Specifically, the first transistor 110 includes one or more (e.g. two) first channel structures 111, first S/D regions 115 and at least one first gate structure 113 while the second transistor 120 includes one or more (e.g. two) second channel structures 121, second S/D regions 125 and at least one second gate structure 123. Since the first transistor 110 is similar to the second transistor 120, consider the first transistor 110 for example. In the examples of FIGS. 1A-1C, the first S/D regions 115 are in direct contact with both of the first channel structures 111 so each of the first S/D regions 115 is configured to function as a common S/D region for the first transistor 110. The first gate structure 113 is also in direct contact with both of the first channel structures 111 and configured to function as a common gate structure. As a result, the first transistor 110 and the second transistor 120 each include a gate-all-around (GAA) multi-channel transistor. Of course it should be understood that the semiconductor device 100 can include any number of stacks 140 arranged in the XY plane over the base 101. The stack 140 can include any number of transistors arranged in the Z direction. Each transistor may include any number of channel structures arranged in the Z direction, while respective S/D regions and gate structures can be configured to electrically connect to any number of channel structures.

Note that each channel structure includes a respective non-epitaxial compound semiconductor. A “non-epitaxial compound semiconductor” herein refers to a compound semiconductor that does not need to be formed by epitaxy and yet may be crystalline, in contrast to traditional semiconductors (such as elemental semiconductors, e.g. Si and Ge, and epitaxial compound semiconductors, e.g. GaN, GaAs, InP and InGaN) as mentioned earlier. A non-epitaxial compound semiconductor can include an oxide semiconductor or a semiconducting oxide, such as In₂O₃, SnO₂, InGaZnO, CdO, ZnO, SnO and the like. A non-epitaxial compound semiconductor can also include a metal chalcogenide, such as a transition-metal dichalcogenide (TMDC). A TMDC can have a chemical formula of MX₂, where M includes a transition metal from Group VI, Group V or Group VI of the periodic table while X includes a chalcogen such as sulfur (S), selenium (Se) or tellurium (Te). More specifically, a TMDC can include a W-based material (e.g. WS₂, WSe₂ or WTe2), a Mo-based material (e.g. MoS₂, MoSe₂ or MoTe2), HfS₂, ZrS₂, TiS₂ or the like. A metal chalcogenide may also include a metal monochalcogenide (e.g. GaSe, InSe or SnS), a metal trichalcogenide (e.g. TiS₃) or the like. In the following descriptions, examples of oxide semiconductors will be used for illustrative purposes.

Note that at least two channel structures can include different chemical compositions from one another. That is, the channel structures can include different semiconductor materials, different dopants and/or different dopant concentration profiles. For instance, the first channel structures 111 may include a different chemical composition from the second channel structures 121. In one example, the first channel structures 111 include p-doped SnO₂ while the second channel structures 121 include n-doped In₂O₃. In another example, the first channel structures 111 include n-doped In₂O₃ while the second channel structures 121 include p-doped SnO₂. Alternatively, at least two channel structures can include a same chemical composition. For instance, the first channel structures 111 and the second channel structures 121 can both include p-doped SnO₂ or both include n-doped In₂O₃. Additionally, the channel structures can have various shapes or geometry, such as nanosheets.

In some embodiments, the gate structures (e.g. 113 and 123) each include at least one gate metal, such as a work function metal (WFM) (e.g. 114 and 124), and at least one gate dielectric (e.g. 112 and 122). As can be appreciated, the WFMs 114 and 124 which function as the gate conductors may be the same as or different from each other, and the gate dielectrics 112 and 122 may also be the same as or different from each other, depending on respective channel structures (i.e. 111 and 121), design requirements (e.g. gate threshold voltage), etc. In this example, the WFM 114 is disposed all around the first channel structures 111 while the WFM 124 is disposed all around the second channel structures 121. Therefore, the first gate structure 113 and the second gate structure 123 can both be configured to function as common gate structures for multiple channel structures. In other examples (not shown), the first gate structures 113 and/or the second gate structures 123 may be disposed all around a single channel structure. While the WFM 114 and 124 are both shown as a single material, they may each be made up of two or more layers of metals having different work functions. Similarly, the gate dielectric 112 and 122 may be made up of two or more layers of dielectric materials.

Note that the S/D regions include non-epitaxial material, similar to the channel structures. For instance, the first S/D regions 115 and the second S/D regions 125 can both include metal material. In the example of FIG. 1B, the first S/D regions 115 and the second S/D regions 125 are configured to electrically connect to a plurality of (e.g. two) channel structures. In alternative embodiments, the first S/D regions 115 and/or the second S/D regions 125 may be in direct contact with only one respective channel structure. Accordingly, the semiconductor device 100 can include one or more single-channel transistors.

Further, inner spacers (e.g. 119 and 129) can be disposed on ends of the gate structures (e.g. 113 and 123). The inner spacers (e.g. 119) are insulating and therefore can separate the gate structures (e.g. 113) from respective S/D regions (e.g. 115). Additionally, the base 101 can, for example, be a substrate or a layer positioned over a substrate. Since a non-epitaxial compound semiconductor need not be formed by epitaxy, the base 101 can include any suitable material, such as a dielectric material in one embodiment or a semiconductor material in another embodiment.

In some embodiments, the semiconductor device 100 can include dielectric materials, e.g. as shown by 103, 112, 122, 131, 133, 119, 129 and 146. The dielectric materials may also be referred to as isolation structures, isolation layers, diffusion breaks, inner spacers, gate dielectrics, capping layers, etc. depending on functions thereof. For example, the dielectric material 131 can be used to separate the first S/D regions 115 from the second S/D regions 125 and thus be referred to as an isolation structure or a diffusion break. Similarly, the dielectric material 133 can separate the first gate structure 113 from the second gate structure 123 and thus be referred to as an isolation structure. Additionally, some of the dielectric materials may include identical materials or may include different materials. For example, the dielectric material 131 and the inner spacers 119 and 129 may include a same material.

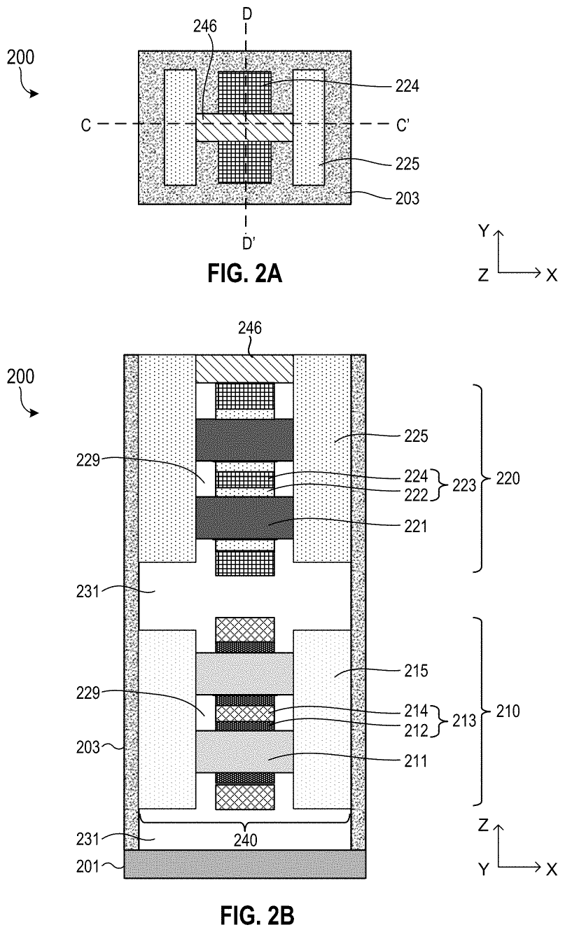

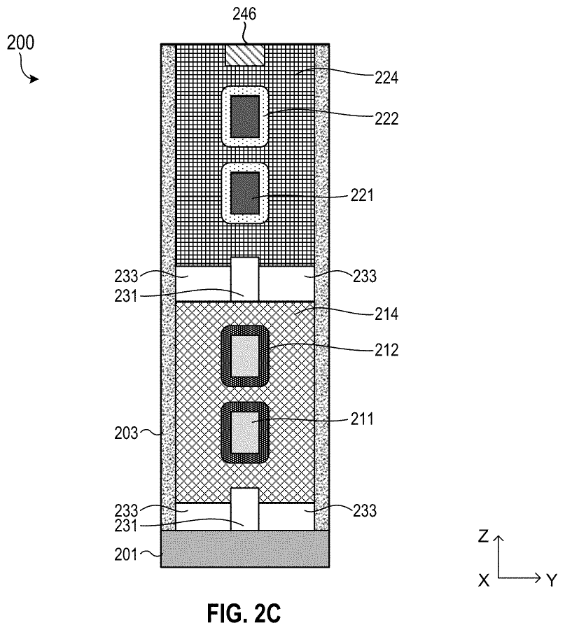

FIG. 2A shows a top view of a semiconductor device 200, in accordance with another embodiment of the present disclosure. FIGS. 2B and 2C respectively show vertical cross-sectional views taken along the line cuts CC′ and DD′ in FIG. 2A, in accordance with some embodiments of the present disclosure. Since the embodiment of the semiconductor device 200 is similar to the embodiment of the semiconductor device 100, descriptions herein will be provided with emphasis places on difference.

Note that similar or identical components are labeled with similar numerals unless specified otherwise. Specifically, a first transistor 210 can correspond to the first transistor 110. A second transistor 220 can correspond to the second transistor 120. Channel structures (e.g. 211 and 221) can correspond to the channel structures (e.g. 111 and 121). Gate structures (e.g. 213 and 223) can correspond to the gate structures (e.g. 113 and 123). WFMs (e.g. 214 and 224) can correspond to the WFMs (e.g. 114 and 124). Gate dielectrics (e.g. 212 and 222) can correspond to the gate dielectrics (e.g. 112 and 122). S/D regions (e.g. 215 and 225) can correspond to the S/D regions (e.g. 115 and 125). Inner spacers (e.g. 219 and 229) can correspond to the inner spacers (e.g. 119 and 129). A base 201 can correspond to the base 101. A dielectric material 203 can correspond to the dielectric material 103.

Herein, first S/D regions 215 and second S/D regions 225 include non-epitaxial material, such as metal material. The first S/D regions 215 and the second S/D regions 225 can have relatively regular shapes, compared to the first S/D regions 115 and the second S/D regions 125. For example, the first S/D regions 215 and the second S/D regions 225 can have a rectangular cross-section in the XZ plane. The first S/D regions 215 and the second S/D regions 225 may further be in direct contact with the dielectric material 203. Similarly, WFMs 214 and 224 can have relatively regular shapes, compared to the WFMs 114 and 124, and be in direct contact with the dielectric material 203.

As can be appreciated, at least two channel structures can include different chemical compositions from one another. That is, the channel structures can include different semiconductor materials, different dopants and/or different dopant concentration profiles. Alternatively, at least two channel structures can include a same chemical composition. Further, the WFMs 214 and 224 which function as the gate conductors may be the same as or different from each other, and the gate dielectrics 212 and 222 may also be the same as or different from each other, depending on respective channel structures (i.e. 211 and 221), design requirements (e.g. gate threshold voltage), etc.

In addition, the semiconductor device 200 can include dielectric materials, e.g. as shown by 203, 212, 222, 231, 233, 219, 229 and 246. The dielectric materials may also be referred to as isolation structures, isolation layers, diffusion breaks, inner spacers, gate dielectrics, capping layers, etc. depending on functions thereof. The dielectric materials may or may include different materials. For example, the dielectric material 231 and the inner spacers 219 and 229 may include a same material.

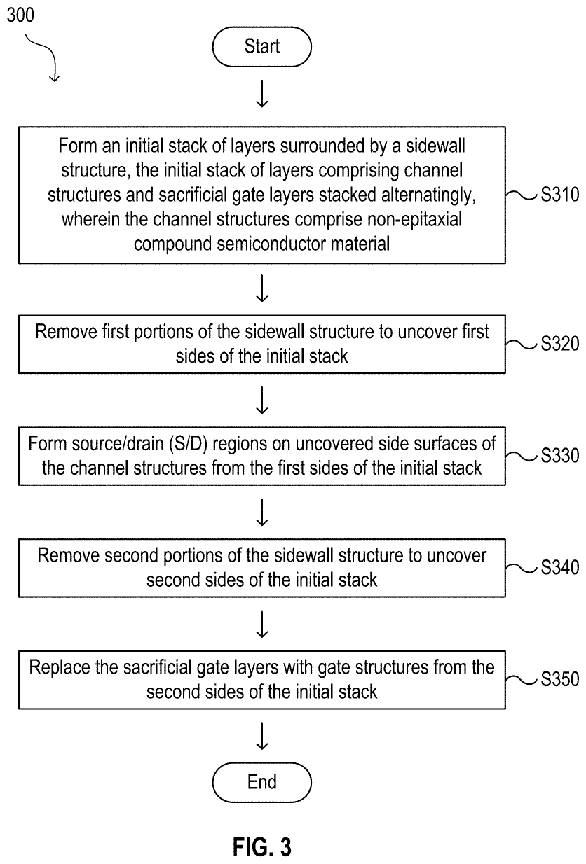

FIG. 3 shows a flow chart of a process for manufacturing a semiconductor device, such as the semiconductor device 100, 200 or the like, in accordance with some embodiments of the present disclosure. The process 300 starts with Step S310 where an initial stack of layers, which is surrounded by a sidewall structure, is formed. The initial stack of layers includes channel structures and sacrificial gate layers stacked alternatingly. The channel structures include non-epitaxial compound semiconductor material. The process 300 then proceeds to Step S320 by removing first portions of the sidewall structure to uncover first sides of the initial stack. At Step S330, source/drain (S/D) regions are formed on uncovered side surfaces of the channel structures from the first sides of the initial stack. At Step S340, second portions of the sidewall structure are removed to uncover second sides of the initial stack. At Step S350, the sacrificial gate layers are replaced with gate structures from the second sides of the initial stack.

Various process flows will be described. One process flow uses a 3D nanosheet stack of dielectric and conductive dielectric channels deposited in the original stack to form gate-all-around structure. This flow is a PMOS over NMOS stack (or an NMOS over PMOS stack) of horizontal nanosheets with NMOS and PMOS conductive dielectric channels for CFET application. Alternative options are also enabled. In one example, nanosheet with p-doped tin oxide (SnO₂) and n-doped indium oxide (In₂O₃). For instance, about three lithography steps are executed for double nanosheet p-n transistors, with non-epitaxial compound semiconductors or conductive dielectrics. In another example, source-drain contact metal is deposited by deposit-fill techniques which eliminate the need of selective disposition. For instance, two gate contact metals are deposited by deposit-fill techniques which eliminate the need of selective disposition. In yet another example, a single conductive (semiconducting) oxide instead of two different conductive (semiconducting) oxides are used for two separate transistors. Thus, source-drain contacts and gate contacts are same. In yet another example, a single conductive (semiconducting) oxide instead of two different conductive (semiconducting) oxides are used for two separate transistors. Thus, source-drain contacts and gate metals are different to have different work function metals which lead to different threshold voltage of nanosheets devices. In yet another example, instead of two separate transistors, a single transistor with a single or multiple nanosheets or a plurality of transistors can be formed. This provides a stack of N tall (i.e. N transistors). Besides, shorted source-drain contacts, shorted gate metals, and any combination of options/examples can be included in such a vertical 3D stack. Designs are not limited.

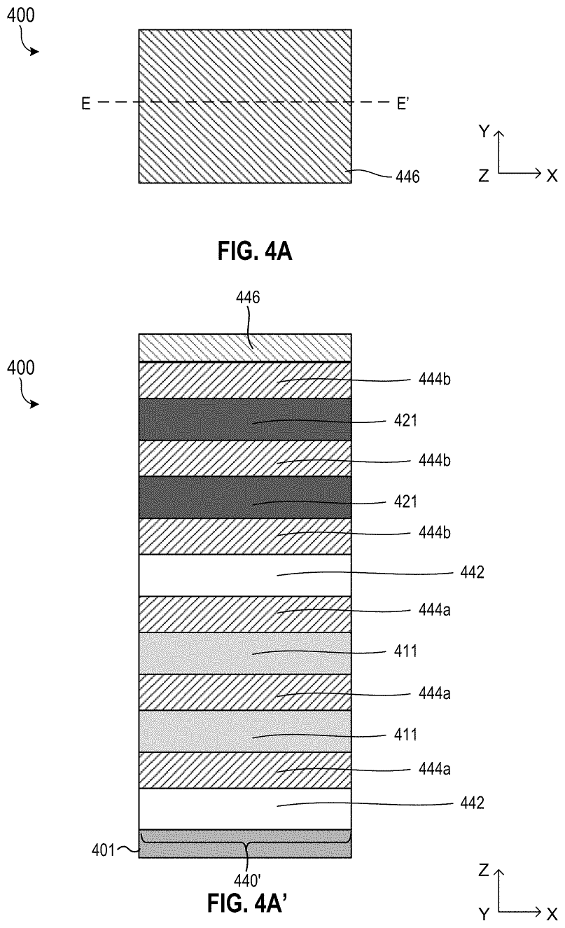

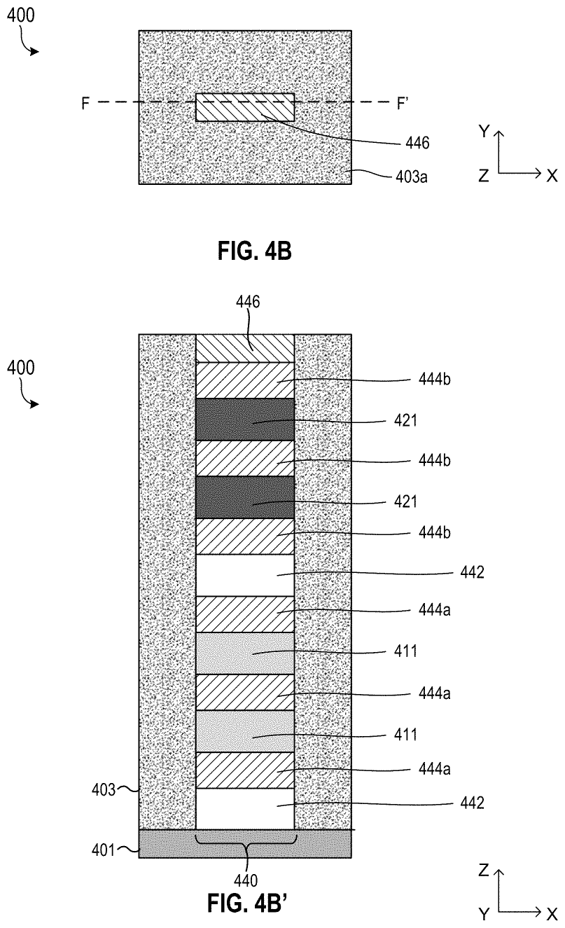

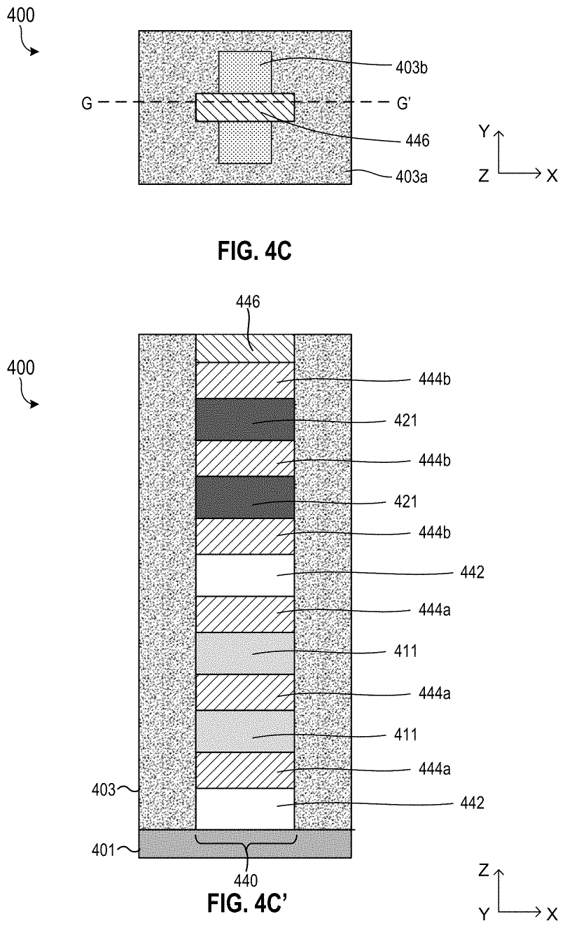

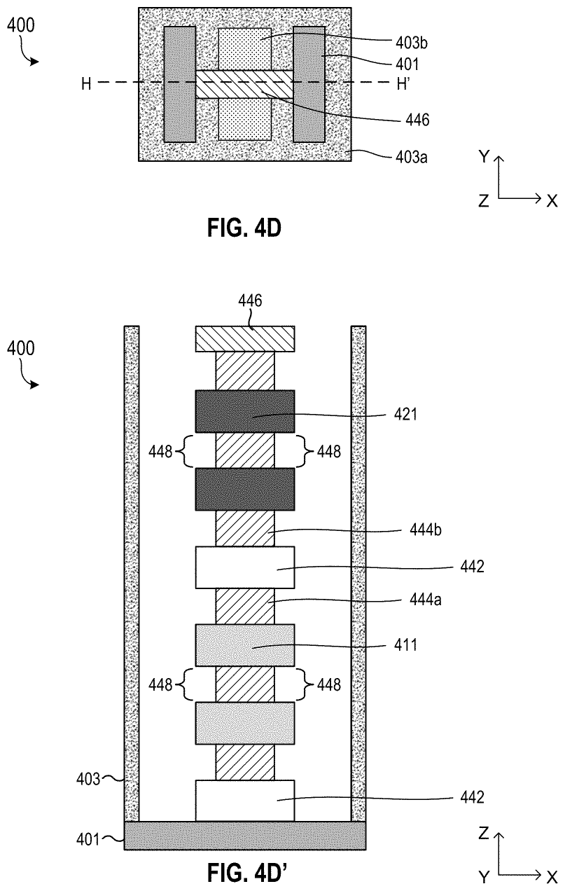

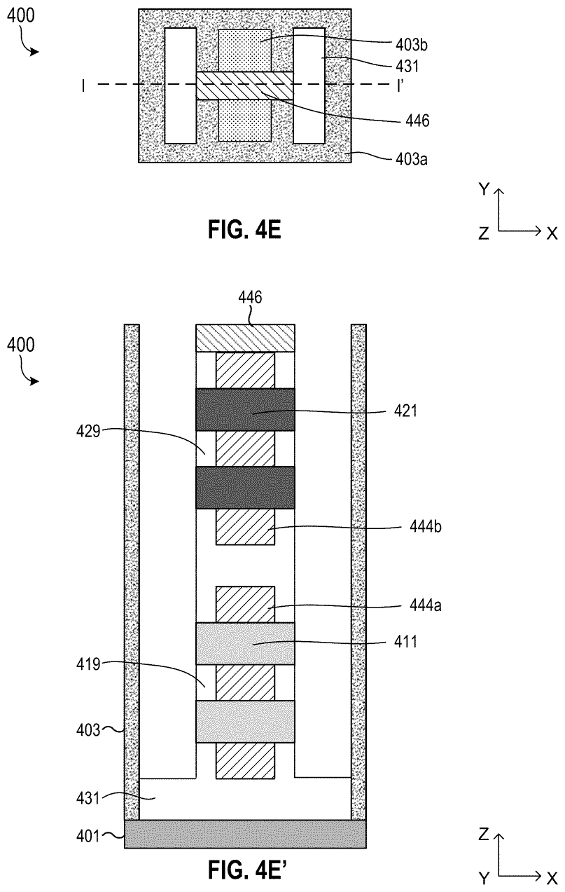

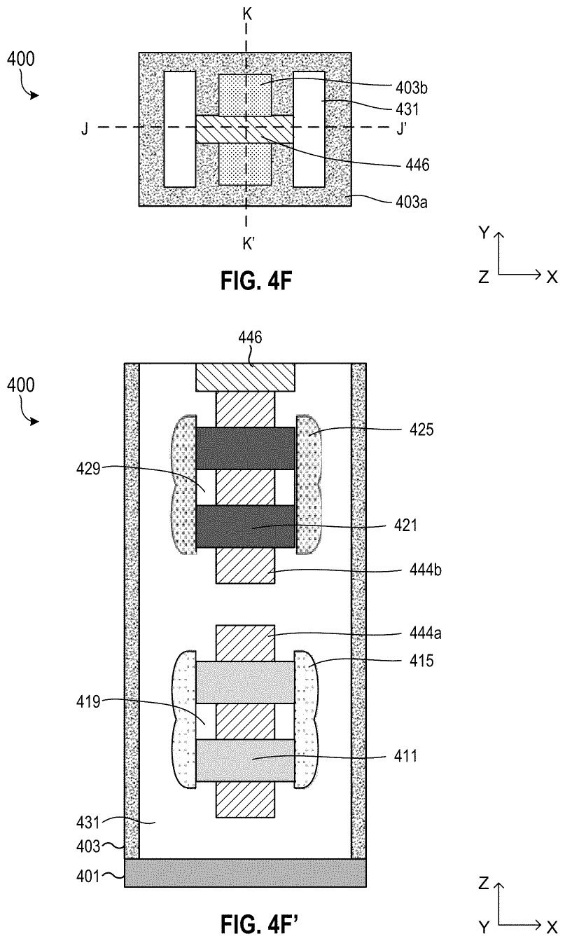

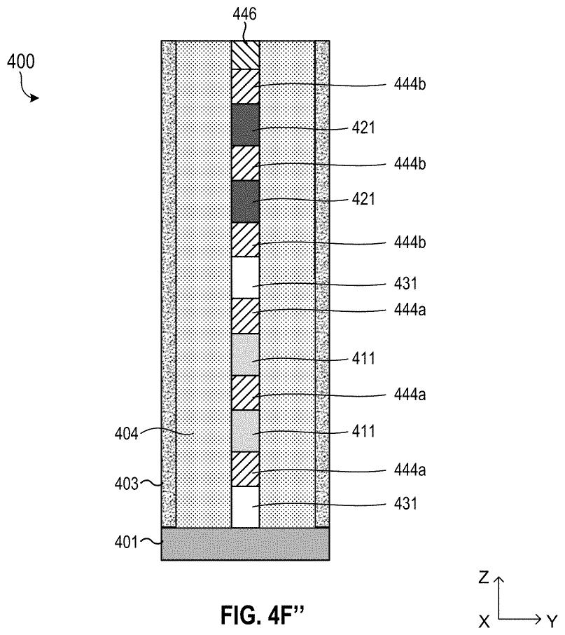

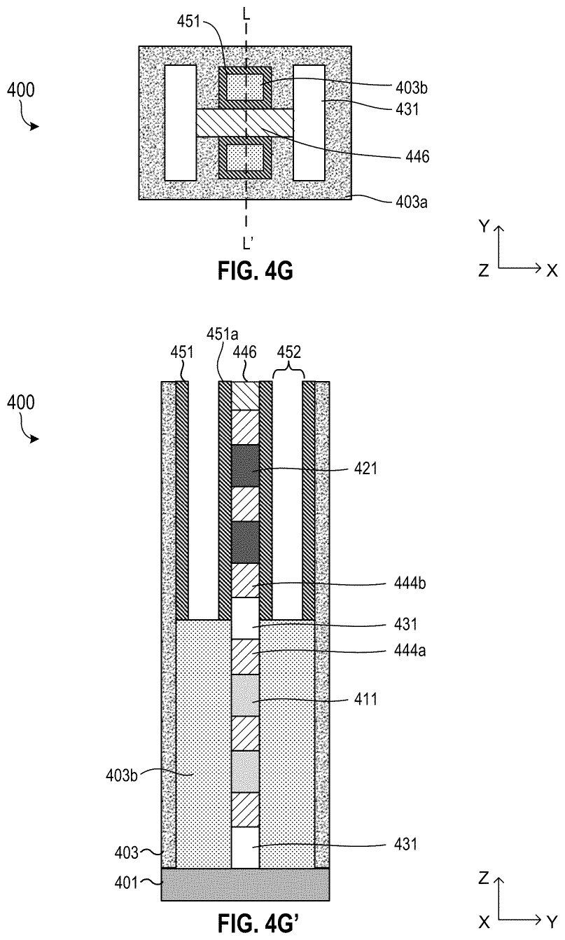

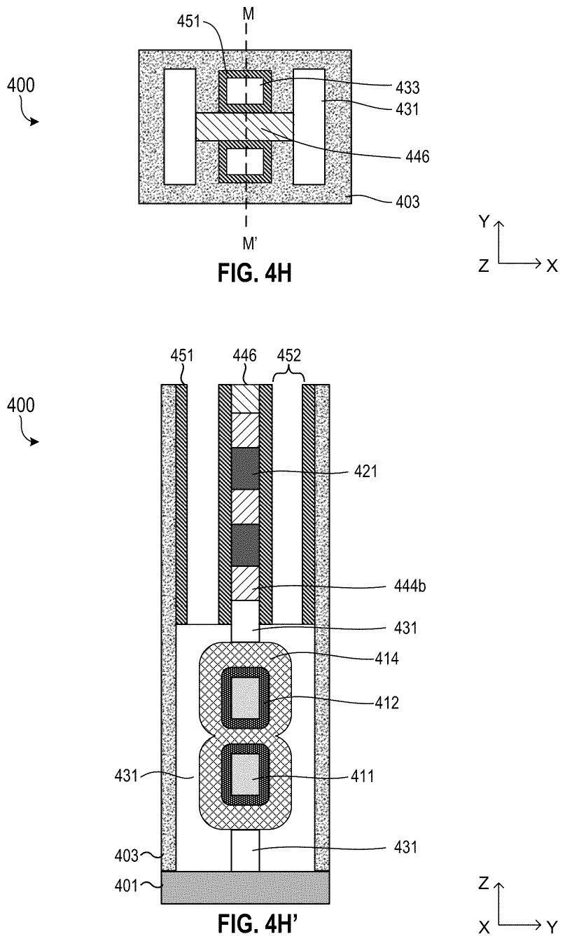

FIGS. 4A, 4B, 4C, 4D, 4E, 4F, 4G and 4H show top views of a semiconductor device 400 at various intermediate steps of manufacturing, such as the process 300, in accordance with some embodiments of the present disclosure. FIGS. 4A′, 4B′, 4C′, 4D′, 4E′ and 4F′ can respectively show vertical cross-sectional views (e.g. in the XZ plane) of the semiconductor device 400 taken along the line cuts EE′, FF′, GG′, HH′, II′ and JJ′ in FIGS. 4A, 4B, 4C, 4D, 4E and 4F. FIGS. 4F″, 4G′ and 4H′ can respectively show vertical cross-sectional views (e.g. in the YZ plane) of the semiconductor device 400 taken along the line cuts KK′, LL′ and MM′ in FIGS. 4F, 4G and 4H. In some embodiments, the semiconductor device 400 can eventually become the semiconductor device 100 or the like.

As shown in FIGS. 4A and 4A′, the semiconductor device 400 includes a base 401 and a stack 440′ of layers formed thereon. The stack 440′ of layers can include alternating layers of dielectric material (e.g. 442, 444a, 444b and 446) and non-epitaxial compound semiconductor material (e.g. 411 and 421) stacked in the Z direction. Note that epitaxy is not needed for forming the stack 440′ of layers. The base 401 can correspond to the base 101 and include any suitable material, such as a dielectric material or a semiconductor material.

In one example, the semiconductor device 400 includes nanosheets with p-doped tin oxide, SnO₂ (e.g. 421) and nanosheets with n-doped indium oxide, In₂O₃ (e.g. 411). Three lithography steps can be executed for double nanosheet p-n transistors, and no epitaxy is needed because epitaxial material is replaced by non-epitaxial compound semiconductors or conductive (semiconducting) dielectrics.

In FIGS. 4B and 4B′, the stack 440′ of layers is directionally etched to form an initial stack 440 of layers. A first dielectric material 403a is then deposited around the initial stack 440 of layers to form a sidewall structure 403. For example, a nanosheet mask can be formed and then the stack 440′ is directionally etched through all the layers with etch stop at the base 401. The first dielectric material 403a is deposited to fill empty space around the initial stack 440 of layers and then planarized via CMP (chemical-mechanical polishing).

As shown, the initial stack 440 of layers include channel structures (e.g. as shown by 411 and 421) and sacrificial gate layers 444 (e.g. as shown by 444a and 444b) stacked alternatingly in the Z direction. In a non-limiting example, the channel structures can include one or more (e.g. two) first channel structures 411 and one or more (e.g. two) second channel structures 421. Accordingly, the sacrificial gate layers 444 can include first sacrificial gate layers 444a, which are in direct contact with the first channel structures 411, and second sacrificial gate layers 444b which are in direct contact with the second channel structures 421. The initial stack 440 can further include (sacrificial) isolation layers 442 and a capping layer 446 (e.g. a hard mask dielectric). The (sacrificial) isolation layers 442 can be directly used as isolation structures, for example between future transistors or between a future transistor and the base 401, or replaced with isolation structures.

The channel structures include non-epitaxial compound semiconductor material while the sacrificial gate layers 444 and the (sacrificial) isolation layers 442 include dielectric material. Therefore, the channel structures, the sacrificial gate layers 444 and the (sacrificial) isolation layers 442 can be configured to be etch selective to each other. In one example, the first channel structures 411 can include a first non-epitaxial compound semiconductor such as p-doped SnO₂ while the second channel structures 421 can include a second non-epitaxial compound semiconductor such as n-doped In₂O₃. In another example, the first channel structures 411 can include n-doped In₂O₃ while the second channel structures 421 can include p-doped SnO₂. In yet another example, the first channel structures 411 and the second channel structures 421 can both include n-doped In₂O₃ or both include p-doped SnO₂.

In some embodiments, the first channel structures 411 can correspond to the first channel structures 111. The second channel structures 421 can correspond to the second channel structures 121. The first sacrificial gate layers 444a can be used to form a first gate structure, which corresponds to the first gate structure 113, as well as form inner spacers, which correspond to the inner spacers 119. The second sacrificial gate layers 444b can be used to form a second gate structure, which corresponds to the second gate structure 123, as well as form inner spacers, which correspond to the inner spacers 129. Additionally, the first dielectric material 403a can correspond to the dielectric material 103.

As a result, the initial stack 440 can eventually become the stack 140 or the like. Accordingly, it should be understood that any number of the initial stacks 440 can be formed over the base 401 by the aforementioned directional etching. Each initial stack 440 can include any number of first channel structures 411 and any number of second channel structures 421. Each initial stack 440 can include any number of (sacrificial) isolation layers 442 (for forming future isolation between transistors).

In an alternative embodiment (not shown), in order to form the semiconductor device 400 shown in FIGS. 4B and 4B′, firstly, a first layer of the first dielectric material 403a can be formed on the base 401. Secondly, an opening can be formed within the first layer (for example by patterning with a trench rectangular mask), and the opening uncovers the base 401. Thirdly, the initial stack 440 can be formed within the opening.

In FIGS. 4C and 4C′, a second dielectric material 403b is optionally deposited, for example by directionally etching the first dielectric material 403a to the base 401 using a nanosheet gate mask, striping off photoresist, and depositing the second dielectric material 403b, followed by a planarization process such as chemical mechanical planarization (CMP). The second dielectric material 403b can be used to protect future gate regions and make (or function as) dummy gates. The sidewall structure 403 thus includes the first dielectric material 403a and the second dielectric material 403b.

In FIGS. 4D and 4D′, first portions of the sidewall structure 403 are removed to uncover one or more first sides (e.g. the −X and +X sides) of the initial stack 440. A mask is used to remove only the first portions, while preserving second portions (e.g. the second dielectric material 403b). Then, indentations 448 are formed by removing end portions of the sacrificial gate layers 444 from the first sides of the initial stack 440. For example, a nanosheet source-drain mask can be used or formed, and then the first dielectric material 403a is directionally etched with an etch stop layer as the base 401. The photoresist mask (i.e. the nanosheet source-drain mask) is then removed. Next, the sacrificial gate layers 444 are recess-etched for forming isolation between future source-drain and gate structures. For instance, different etch rates of the sacrificial gate layers 444, the (sacrificial) isolation layers 442 and the channel structures permit an etch process step to form indentations 448.

In FIGS. 4E and 4E′, a third dielectric material 431 is deposited from the first sides of the initial stack 440, optionally planarized by CMP, and directionally etched back to form inner spacers 419 and 429, which can respectively correspond to the inner spacers 129 and 429. In this example, a portion of the third dielectric material 431 remains on the base 401. In another embodiment (not shown), the third dielectric material 431 can be etched all the way to uncover the base 401 if the base 401 is non-conductive. Note that the third dielectric material 431 includes a same material as the (sacrificial) isolation layers 442 in this example. Thus, the (sacrificial) isolation layers 442 will hereinafter be labeled and/or referred to as the third dielectric material 431 for simplicity.

In FIGS. 4F, 4F′ and 4F″, first S/D regions 415 and second S/D regions 425 are formed on respective ends of the first channel structures 411 and the second channel structures 421. For example, a first metal can be selective deposited or grown on the first non-epitaxial compound semiconductor (i.e. the first channel structures 411) to form the first S/D regions 415. Then, a second metal can be selective deposited or grown on the second non-epitaxial compound semiconductor (i.e. the second channel structures 421) to form the second S/D regions 425. Next, a fill can be deposited with the third dielectric material 431, followed by planarization by CMP. Note that processes for depositing/growing the first metal and/or the second metal need not include epitaxy. The first S/D regions 415 and the second S/D regions 425 can respectively correspond to the first S/D regions 115 and the second S/D regions 125. In another embodiment, the first S/D regions 415 and the second S/D regions may be formed in a same deposition process when the first channel structures 411 and the second channel structures 421 include a same compound semiconductor.

In FIGS. 4G and 4G′, a protective structure 451 (e.g. a dielectric material) is formed to cover side surfaces of the second channel structures 421 from second sides (e.g. the +Y and —Y sides) of the initial stack 440. Specifically, the second dielectric material 403b can be etched back (midway) to uncover the side surfaces of the second channel structures 421 while still leaving side surfaces of the first channel structures 411 covered.

Subsequently, a protective material (e.g. as partially shown by 451), which is etch selective to the second dielectric material 403b, can be formed (for example by atomic layer deposition) over the second dielectric material 403b to cover the side surfaces of the second channel structures 421 (and optionally planarized). Next, the protective material can be directionally etched to partially uncover the second dielectric material 403b, for example by forming an opening 452, such that a remaining portion of the protective material forms the protective structure 451. Note that the protective structure 451 has a shape of a hollow rectangle in the top view in the FIG. 4G example. It should be understood that the protective structure 451 can have any suitable shape as long as the protective structure 451 includes a portion 451a that covers the first sides of the initial stack 440.

In FIGS. 4H and 4H′, the second dielectric material 403b is further etched by selectively etching through the opening 452, which may for example include a first directional etching process and a second isotropic etching process. Consequently, side surfaces of the first sacrificial gate layers 444a are uncovered from the second sides of the initial stack 440 so that the first sacrificial gate layers 444a can be replaced with one or more gate structures. For example, the first sacrificial gate layers 444a can be removed by selective etching. Then, at least one gate dielectric 412 can be selectively deposited around the first channel structures 411 before at least one gate metal, such as a WFM 414 is selectively deposited on the at least one gate dielectric 412. Next, the third dielectric material 431 is deposited and etched back. Note that the WFM 414 can correspond to the WFM 114. The at least one gate dielectric 412 can correspond to the at least one gate dielectric 112.

While not shown, the protective structure 451 can be removed to uncover side surfaces of the second sacrificial gate layers 444b from the second sides of the initial stack 440 so that the second sacrificial gate layers 444b can be replaced with a gate structure which correspond to the second gate structure 123. Therefore, the semiconductor device 400 will eventually become the semiconductor device 100.

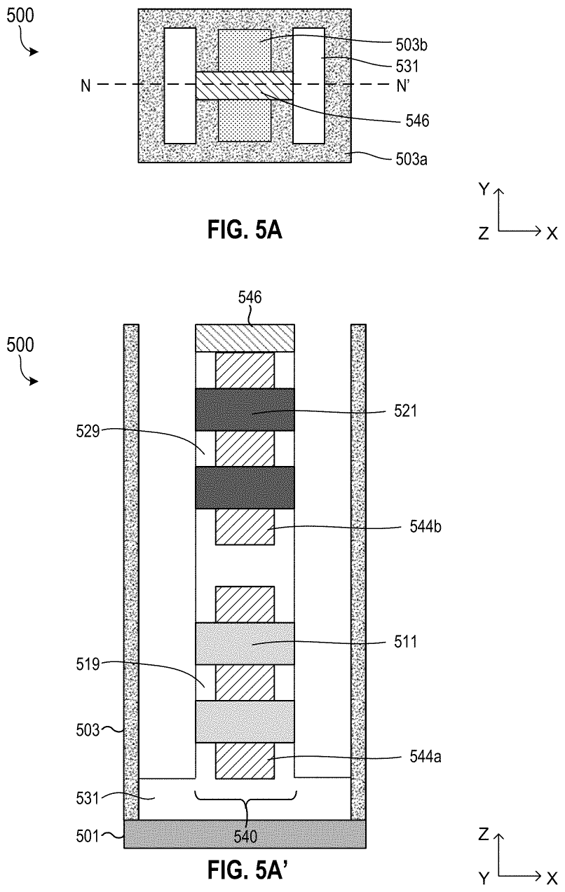

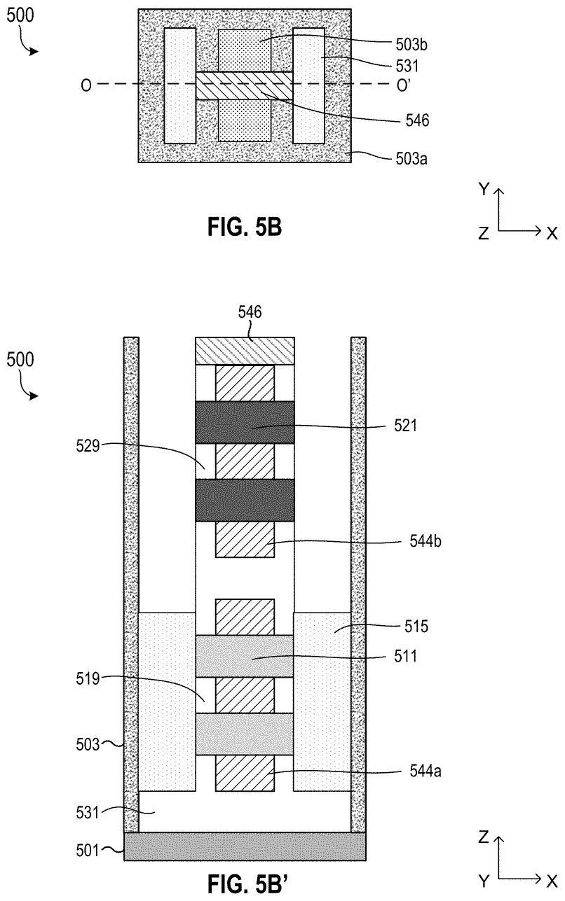

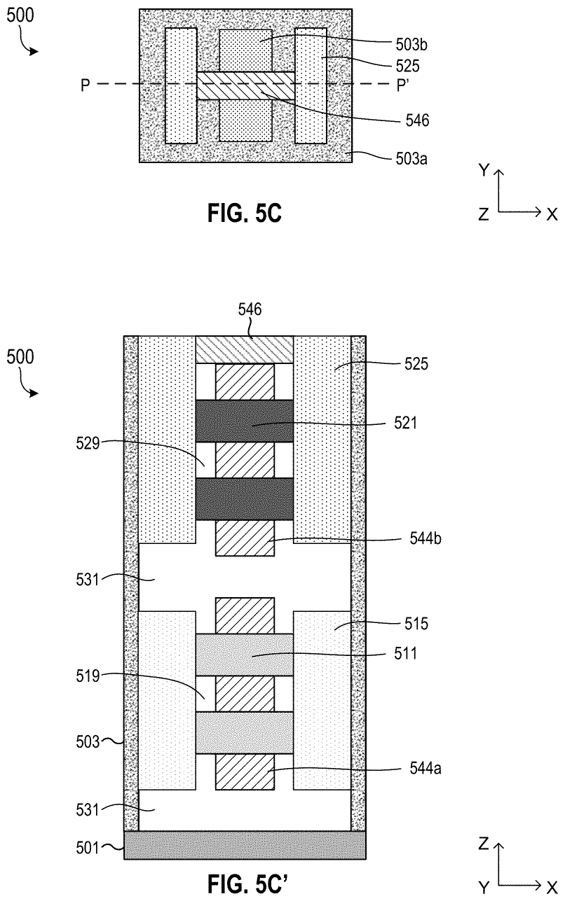

FIGS. 5A, 5B and 5C show top views of a semiconductor device 500 at various intermediate steps of manufacturing, such as the process 300, in accordance with some embodiments of the present disclosure. FIGS. 5A′, 5B′ and 5C′ can respectively show vertical cross-sectional views of the semiconductor device 500 taken along the line cuts NN′, 00′ and PP′ in FIGS. 5A, 5B and 5C. Herein, source-drain contact metal can be deposited by deposit-fill techniques which eliminate the need of selective disposition. For instance, two gate contact metals can be deposited by deposit-fill techniques which eliminate the need of selective disposition. In some embodiments, the semiconductor device 500 can eventually become the semiconductor device 200 or the like.

The semiconductor device 500 in FIGS. 5A and 5A′ can correspond to the semiconductor device 400 FIGS. 4E and 4E′. Specifically, a base 501 can correspond to the base 401. First channel structure 511 can correspond to the first channel structure 411. Second channel structure 521 can correspond to the second channel structure 421. Sacrificial gate layers (e.g. 544a and 544b) can correspond to the sacrificial gate layers (e.g. 444a and 444b). A capping layer 546 can correspond to the capping layer 446. A first dielectric material 503a can correspond to the first dielectric material 403a. A second dielectric material 503b can correspond to the second dielectric material 403b. A sidewall structure 503 can correspond to the sidewall structure 403. A third dielectric material 531 can correspond to the third dielectric material 431. Inner spacers 519 and 529 can respectively correspond to the inner spacers 419 and 429. An initial stack 540 of layers can correspond to the initial stack 440 of layers. Further, the semiconductor device 500 in FIGS. 5A and 5A′ can be formed in a similar way, for example by processes shown in FIGS. 4A-4E and 4A′-4E′. The descriptions have been provided above and will be omitted for simplicity purposes.

In FIGS. 5B and 5B′, a first metal (e.g. as partially shown by 515) can be deposited from first sides (e.g. the —X and +X sides) of the initial stack 540, planarized by CMP and etched back to form first S/D regions 515. Note that the first metal is deposited in a non-selectively manner. The first S/D regions 515 can correspond to the first S/D regions 215.

In FIGS. 5C and 5C′, an isolation structure (as shown by 531) is formed, for example by depositing the third dielectric material 531 over the first S/D regions 515 and below the second channel structures 521, which may involve etching back. Subsequently, a second metal is non-selectively deposited and planarized to form the second S/D regions 525, which can correspond to the second S/D regions 425.

While not shown, the semiconductor device 500 may then go through processes similar to what is shown in FIGS. 4G-4H and 4G′-4H′. Such processes can include forming a protective structure covering second sacrificial gate layers 544b, replacing first sacrificial gate layers 544a with a first gate structure, removing the protective structure and replacing the second sacrificial gate layers 544b with a second gate structure. Note that at least one gate metal and/or at least one gate dielectrics of the first gate structure and the second gate structure can be deposited non-selectively. Consequently, the semiconductor device 500 will eventually become the semiconductor device 200.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “wafer” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

The substrate can be any suitable substrate, such as a silicon (Si) substrate, a germanium (Ge) substrate, a silicon-germanium (SiGe) substrate, and/or a silicon-on-insulator (SOI) substrate. The substrate may include a semiconductor material, for example, a Group IV semiconductor, a Group III-V compound semiconductor, or a Group II-VI oxide semiconductor. The Group IV semiconductor may include Si, Ge, or SiGe. The substrate may be a bulk wafer or an epitaxial layer.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A semiconductor device, comprising:
a stack of transistors stacked over a base in a direction substantially perpendicular to a working surface of the base, each transistor comprising a respective channel structure, respective source/drain (S/D) regions positioned on ends of the respective channel structure, and a respective gate structure disposed all around the respective channel structure,
wherein each channel structure comprises a respective non-epitaxial compound semiconductor.

2. The semiconductor device of claim 1, wherein:
at least two channel structures comprise a same chemical composition.

3. The semiconductor device of claim 1, wherein:
at least two channel structures comprise different chemical compositions.

4. The semiconductor device of claim 1, wherein:
at least one non-epitaxial compound semiconductor is an oxide semiconductor or a metal chalcogenide.

5. The semiconductor device of claim 4, wherein:
the oxide semiconductor is In₂O₃, SnO₂, InGaZnO, ZnO, SnO or CdO.

6. The semiconductor device of claim 4, wherein:
the metal chalcogenide is WS₂, WSe₂, WTe₂, MoS₂, MoSe₂, MoTe₂, HfS₂, ZrS₂, TiS₂, GaSe, InSe or TiS₃.

7. The semiconductor device of claim 1, wherein:
one or more S/D regions comprise a metal.

8. The semiconductor device of claim 1, wherein:
at least one transistor comprises a plurality of channel structures,
respective S/D regions of the at least one transistor are in direct contact with the plurality of channel structures, and
a respective gate structure of the at least one transistor is disposed all around the plurality of channel structures.

9. The semiconductor device of claim 1, further comprising:
inner spacers disposed between gate structures and respective S/D regions.

10. The semiconductor device of claim 1, wherein:
at least one gate structure comprises a gate metal and a gate dielectric.

11. The semiconductor device of claim 1, wherein:
the base is positioned immediately below the stack of transistors, and
the base comprises a dielectric material or a semiconductor material.

12. The semiconductor device of claim 1, further comprising:
isolation structures between transistors.

13. A method of microfabrication, the method comprising:
forming an initial stack of layers surrounded by a sidewall structure, the initial stack of layers comprising channel structures and sacrificial gate layers stacked alternatingly, wherein the channel structures comprise non-epitaxial compound semiconductor material;
removing first portions of the sidewall structure to uncover first sides of the initial stack;
forming source/drain (S/D) regions on uncovered side surfaces of the channel structures from the first sides of the initial stack;
removing second portions of the sidewall structure to uncover second sides of the initial stack; and
replacing the sacrificial gate layers with gate structures from the second sides of the initial stack.

14. The method of claim 13, wherein the forming the S/D regions comprises:
selectively depositing a metal material on uncovered side surfaces of at least one channel structure from the first sides of the initial stack.

15. The method of claim 13, wherein the forming the S/D regions comprises:
depositing a first metal material from the first sides of the initial stack;
etching back the first metal material to form first S/D regions on opposing ends of at least one first channel structure;
forming an isolation structure over the first S/D regions; and
depositing a second metal material to form second S/D regions on opposing ends of at least one second channel structure.

16. The method of claim 13, wherein the sacrificial gate layers including one or more first sacrificial gate layers in direct contact with one or more first channel structures and one or more second sacrificial gate layers in direct contact with one or more second channel structures positioned above the one or more first channel structures, the replacing the sacrificial gate layers with the gate structures comprises:
forming a protective structure to cover respective side surfaces of the one or more second sacrificial gate layers from the second sides of the initial stack; and
replacing the one or more first sacrificial gate layers with one or more first gate structures.

17. The method of claim 16, further comprising:
removing the protective structure; and
replacing the one or more second sacrificial gate layers with one or more second gate structures.

18. The method of claim 16, wherein the removing the second portions of the sidewall structure comprises:
removing upper parts of the second portions of the sidewall structure before the forming the protective structure; and
removing lower parts of the second portions of the sidewall structure after the forming the protective structure.

19. The method of claim 13, further comprising:
forming indentations by removing end portions of the sacrificial gate layers from the first sides of the initial stack; and
forming inner spacers in the indentations.

20. The method of claim 13, wherein the forming the initial stack of layers comprises:
forming a stack of layers, the stack of layers including alternating layers of dielectric material and non-epitaxial compound semiconductor material;
directionally etching the stack of layers to form the initial stack of layers; and
depositing one or more dielectric materials around the initial stack of layers to form the sidewall structure.
